(19) United States
(12) Patent Application Publication
(10) Pub. No.: US 2024/0204023 A1
(43) Pub. Date: Jun. 20, 2024

(54) SOLID-STATE IMAGING DEVICE AND METHOD FOR MANUFACTURING THE SAME

(71) Applicants: TOWER PARTNERS SEMICONDUCTOR CO., LTD., Uozu City (JP); TOWER SEMICONDUCTOR LTD., Migdal Haemek (IL)

(72) Inventors: Yoshiaki NISHI, Kyoto (JP); Toshifumi YOKOYAMA, Toyama (JP)

(73) Assignees: TOWER PARTNERS SEMICONDUCTOR CO., LTD., Uozu City (JP); TOWER SEMICONDUCTOR LTD., Migdal Haemek (IL)

(21) Appl. No.: 18/539,223

(22) Filed: Dec. 13, 2023

(30) Foreign Application Priority Data
Dec. 14, 2022 (JP) 2022-199194

(51) Int. Cl. H01L 27/146

(52) U.S. Cl. CPC H01L 27/14629; H01L 27/14621; H01L 27/14627; H01L 27/14685

(57) ABSTRACT

A solid-state imaging device includes a plurality of pixels arrayed in a two-dimensional matrix on a substrate. Each of the pixels includes a light receiving potion that performs photoelectric conversion, a microlens that condenses light to the light receiving potion, and at least one light scattering structure provided between the light receiving potion and the microlens.

### BACKGROUND

In recent years, there has been a demand for image sensors with high sensitivity to near infrared light (having a wavelength of around 700 to 1100 nm) because such image sensors are suitable for applications in surveillance, distance measurement, authentication, on-vehicle use, sensing, or the like. In particular, there is a great demand for image sensors with high sensitivity at a wavelength of around 940 nm. This is because the wavelength spectrum of sunlight reaching the sea level has few components having a wavelength of around 940 nm and imaging using such an image sensor even during daytime is less affected by sunlight.

Conventionally, in a solid-state imaging device, a photodiode (PD) is formed for each of pixels formed to be arrayed in a two-dimensional matrix on a substrate. A microlens is formed for each of the pixels in order to condense light. Light condensed by the microlens has a high refractive index, that is, about 4, when an Si substrate used, and enters the substrate almost perpendicular thereto. In each PD, a signal charge is generated in accordance with an amount of received incident light.

When an Si substrate is used for an image sensor, near infrared light is less likely to be absorbed. In particular, quantum efficiency in a typical image sensor is about 20% at a wavelength of around 940 nm. In order to increase the quantum efficiency, in general, a depth of the photodiode is increased. However, in order to achieve sufficient absorption, the depth is needed to be 10 μm or more. When the depth of PD is increased, a harmful effect, that is, increase in degree of color mixture with an adjacent pixel, occurs.

To cope with the above-described inconvenience, in Japanese Unexamined Patent Publication No. 2016-001633, a surface of an Si substrate is formed with periodic recesses and projections (for example, recesses and projections in an inverted pyramid type). Thus, Japanese Unexamined Patent Publication No. 2016-001633 discloses a technology in which light is refracted on the substrate surface and an optical path length within the substrate is increased. According to this technology, an amount of absorption of incident light in the Si substrate is increased and the quantum efficiency is increased.

### SUMMARY

In a structure described in Japanese Unexamined Patent Publication No. 2016-001633, the Si substrate surface is processed directly, and thus, an interface level is destabilized. This can cause increase of a dark current and a white scratch (white spot) and thus reduction of image quality, and therefore, it is needed to restore the interface level of the Si substrate surface. Moreover, since the recesses and projections are provided to form inverted pyramid shapes, incidence angle characteristics become irregular, and it is likely that shading, moire, or the like occurs in an image to be output, so that reduction in image quality is caused.

The present disclosure provides a technology that realizes a solid-state imaging device that can increase a quantum efficiency while suppressing reduction in image quality and a method for manufacturing the solid-state imaging device.

A solid-state imaging device according to the present disclosure incudes a plurality of pixels arrayed in a two-dimensional matrix on a substrate. Each of the pixels includes a light receiving portion that performs photoelectric conversion, a microlens that condenses light to the light receiving portion, and at least one light scattering structure provided between the light receiving portion and the microlens.

A method for manufacturing a solid-state imaging device according to the present disclosure includes forming a plurality of light receiving portions arrayed in a two-dimensional matrix on a substrate, and forming a light scattering structure on each of the light receiving potions.

According to the present disclosure, in a solid-state imaging device, a quantum efficiency can be increased while suppressing reduction in image quality.

### BRIEF DESCRIPTION OF THE DRAWINGS

FIG. 1 is a view schematically illustrating a cross section of a solid-state imaging device according to a first embodiment of the present disclosure.

FIG. 2 is a view illustrating a cross section of a solid-state imaging device of a comparative example.

FIG. 3 is a graph illustrating spectroscopic characteristics in a typical image sensor.

FIG. 4 is a graph illustrating incidence angle characteristics in a solid-state imaging device of the present disclosure.

FIG. 5 is a graph illustrating incidence angle characteristics in a solid-state imaging device of a known example.

FIG. 6 is a graph illustrating wavelength-dependence of a refractive index of a color filter.

FIG. 7 is a view schematically illustrating a cross section of a solid-state imaging device of a variation of the first embodiment of the present disclosure.

FIG. 8 is a schematic plan view of a solid-state imaging device according to an embodiment of the present disclosure.

FIG. 9 is a schematic plan view of a solid-state imaging device according to an embodiment of the present disclosure.

FIG. 10 is a schematic plan view of a solid-state imaging device according to an example of the present disclosure.

FIG. 11 is a view schematically illustrating a cross section of a solid-state imaging device according to a second embodiment of the present disclosure.

FIG. 12 is a graph illustrating a quantum efficiency in a solid-state imaging device according to an embodiment of the present disclosure.

FIG. 13 is a graph illustrating a quantum efficiency in a solid-state imaging device according to an embodiment of the present disclosure.

FIG. 14 is a view illustrating a method for manufacturing a solid-state imaging device according to the present disclosure.

FIG. 15 is a view illustrating the method for manufacturing a solid-state imaging device, following FIG. 14.

FIG. 16 is a view illustrating the method for manufacturing a solid-state imaging device, following FIG. 15.

FIG. 17 is a view illustrating the method for manufacturing a solid-state imaging device, following FIG. 16.

FIG. 18 is a view illustrating another method for manufacturing a solid-state imaging device according to the present disclosure.

FIG. 19 is a view illustrating the method for manufacturing a solid-state imaging device, following FIG. 18.

FIG. 20 is a view illustrating the method for manufacturing a solid-state imaging device, following FIG. 19.

FIG. 21 is a view illustrating still another method for manufacturing a solid-state imaging device according to the present disclosure.

FIG. 22 is a view illustrating the method for manufacturing a solid-state imaging device, following FIG. 21.

FIG. 23 is a view illustrating the method for manufacturing a solid-state imaging device, following FIG. 22.

### DETAILED DESCRIPTION

Embodiments of the present disclosure will be described below with reference to the accompanying drawings. Note that a technology disclosed herein is not limited to the embodiments below and each of the embodiments can be changed as appropriate in a range in which effects of the present disclosure can be achieved.

### First Embodiment

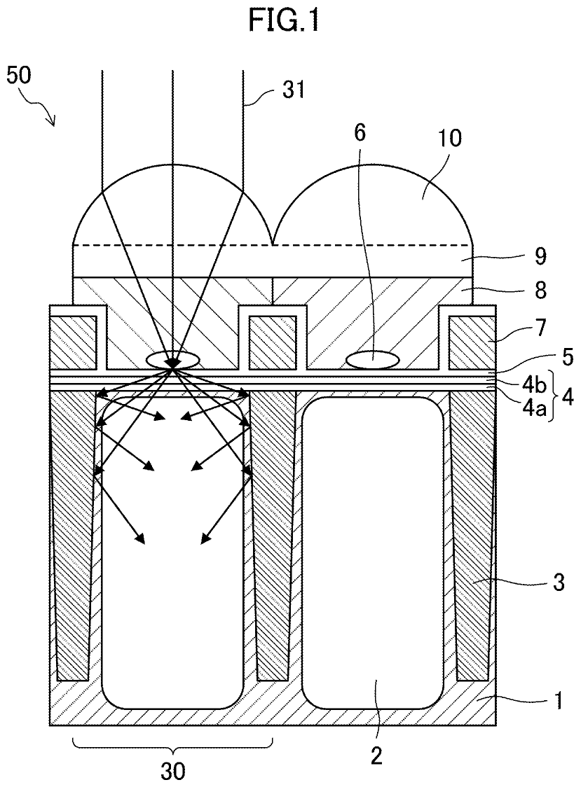

FIG. 1 is a view schematically illustrating a cross section of an exemplary solid-state imaging device 50 according to a first embodiment. The solid-state imaging device 50 includes a plurality of pixels 30 arrayed in a two-dimensional matrix on a substrate 1 that is, for example, a silicon substrate. In FIG. 1, for two pixels, the cross section is illustrated.

Each of the pixels 30 includes a light receiving potion 2 that is provided near a surface of the substrate 1 and generates charges by photoelectric conversion in accordance with incident light 31. The light receiving potion 2 is, for example, a photodiode. A deep trench isolation (DTI) region 3 is formed in the substrate 1 so as to surround the light receiving potion 2. The DTI region 3 is a region that partitions the pixels 30.

An insulating film 4 is formed on the substrate 1. The insulating film 4 includes an insulating film lower layer 4a and an insulating film upper layer 4b. The insulating film lower layer 4a is formed of HfO, SiO2, or the like, stabilizes an interface level of a surface of the substrate 1, and suppresses generation of a dark current and a white scratch (white spot). The insulating film upper layer 4b is formed of a SiN film that has a high refractive index and transparent with light ranging to an ultraviolet wavelength region or the like, and has a reflection preventive effect. A protective film 5 formed of SiO2 or the like is provided on the insulating film 4.

A light shielding layer 7 is formed above the DTI region 3 so as to surround the light receiving potion 2. A recessed portion is formed by the light shielding layer 7 above the light receiving potion 2. Note that the protective film 5 covers also side and upper surfaces of the light shielding layer 7.

A color filter 8 is formed so as to fill the recessed portion formed above the light receiving potion 2. The color filter 8 has a predetermined color for each of the pixels 30 and recesses and protrusions can be generated on an upper surface thereof as a whole. For the recesses and protrusions, a flattening film 9 is formed to cover the color filter 8. A microlens is formed on a flat upper surface of the flattening film 9. Note that the solid-state imaging device 50 can acquire images from both near infrared light and visible light, and the color filter 108 is used for an image formed by visible light.

A light scattering structure 6 is provided between the light receiving potion 2 and the microlens 10. More specifically, the light scattering structure 6 is provided in the color filter 8. In this example, the light scattering structure 6 is located in a position near the light receiving potion 2 in a height direction (a direction perpendicular to a surface of the substrate 1) and near a center of the light receiving potion 2 when viewed from a direction perpendicular to the surface of the substrate 1 (that is, in a plan view). A refractive index of the light scattering structure 6 is set lower than a refractive index of a portion therearound (the color filter 8 in this example).

As illustrated in the pixel 30 at a left side in FIG. 1, the incident light 31 that enters the solid-state imaging device 50 is condensed by the microlens 10. The incident light 31 transmits through the flattening film 9, the color filter 8, or the like and enters the light scattering structure 6. In the light scattering structure 6, reflection, diffraction, and scattering occur due to a difference in refractive index, and the incident light 31 enters the light receiving potion 2 at various angles. As a result, an effective optical path length of the incident light proceeding in the light receiving potion 2 is increased, an amount of absorption of near infrared light is increased, and a quantum efficiency is increased.

With the light shielding layer 7 and the DTI region 3 provided, this effect is increased. As a reason for this, first, the DTI region 3 as a structure in which a trench formed in the substrate 1 by etching or the like is filled with an insulating film, and the DTI region 3 and the substrate 1 have different refractive indexes. Due to a difference between the refractive indexes, diagonally scattered incident light is reflected by the light scattering structure 6 and returns to the light receiving potion 2. As a result, the optical path length in the light receiving potion 2 is further increased and therefore the quantum efficiency is increased. Regarding this, scattering and reflection of the incident light 31 are as indicated by arrows in FIG. 1.

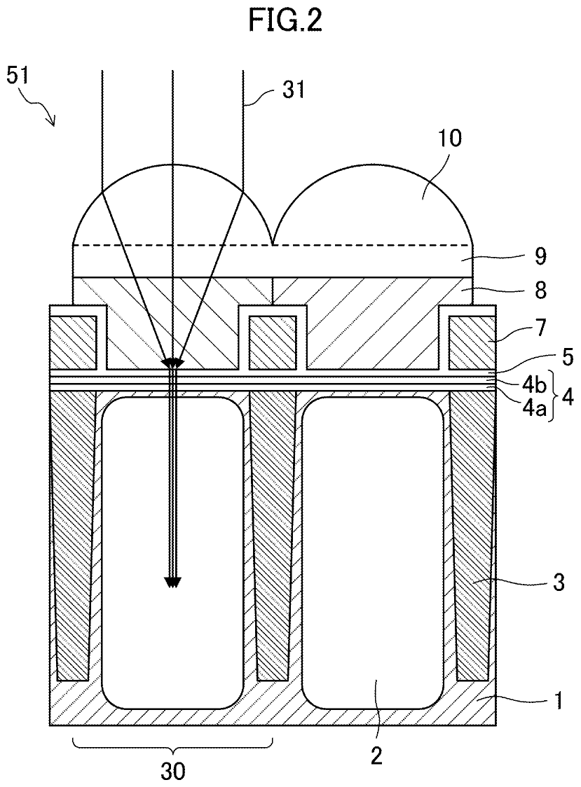

In FIG. 2, a solid-state imaging device 51 of a comparative example is illustrated. The solid-state imaging device 51 is similar to the solid-state imaging device 50 of this embodiment (FIG. 1) except that the solid-state imaging device 51 does not include the light scattering structure 6. Since the solid-state imaging device 51 does not include the light scattering structure 6, incident light condensed by the microlens 10 enters the light receiving potion 2 at an angle nearly perpendicular to the surface of the substrate 1 and proceeds as it is. As a result, as compared to the solid-state imaging device 50, the optical path length in the light receiving potion 2 is short, and therefore, the quantum efficiency is low. In contrast, the solid-state imaging device 50 of this embodiment includes the light scattering structure 6 as described above, so that the quantum efficiency is increased in the solid-state imaging device 50.

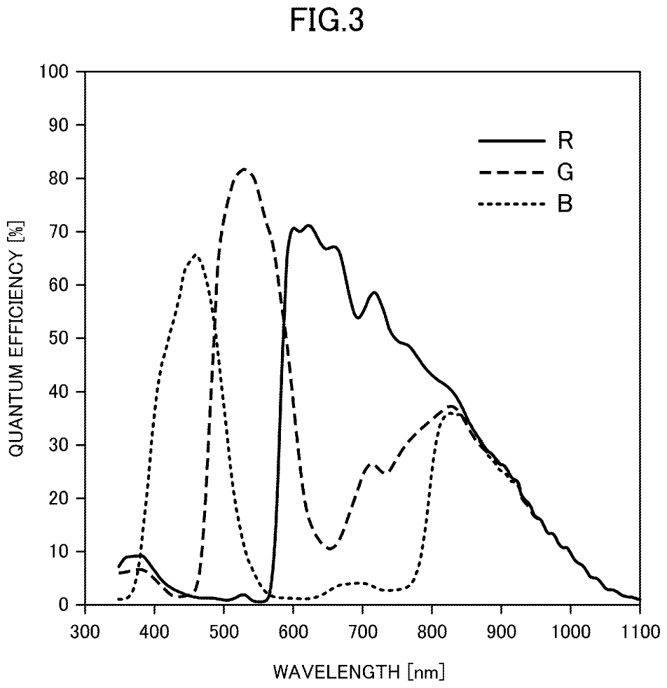

FIG. 3 illustrates spectroscopic characteristics of a typical solid-state imaging device (that may be the solid-state imaging device 51 of the comparative example). Lines R, G, and B indicate spectroscopic characteristics of pixels corresponding to red, green, and blue in this order. As illustrated in FIG. 3, in a near infrared region with a longer wavelength than that of red, as the wavelength increases, an absorption coefficient of the silicon substate reduces and the quantum efficiency reduced. At a wavelength of around 940 nm, the quantum efficiency is about 20%. Therefore, it is effective to increase the optical path length to increase the quantum efficiency.

In order to increase reflection of light by the light scattering structure 6, a difference in refractive index between the light scattering structure 6 and a portion therearound (the color filter 8) is preferably increased. Specifically, from a viewpoint of making reflection, diffraction, and scattering of light in the light scattering structure 6 significant, the difference in refractive index is preferably 0.3 or more, and is more preferably 0.5 or more.

The refractive index of the color filter 8 depends on a wavelength of light, but is generally about 1.6 to 2.0. Therefore, when the refractive index of the light scattering structure 6 is 1.3 or less, an effect of scattering the incident light 31 is reliably achieved.

As a simple method for achieving the above-described difference in refractive index, a proper material may be selected. That is, a material forming the light scattering structure 6 is selected such that a refractive index of the material is lower than a refractive index of a material forming the portion therearound.

For example, while the color filter 8 is formed of an organic acrylic film, the light scattering structure 6 may be formed of an organic film with a low refractive index containing a silicon filler.

As for the light scattering structure 6, the light scattering structure 6 may be formed as a void (a cavity, a hollow structure) provided in the color filter 8 or the like. In this case, since a refractive index of air is 1, a difference in refractive index between the light scattering structure 6 and the portion therearound is increased, and a more significant effect is achieved. When the light scattering structure 6 is provided in a position near a light-condensing point of the microlens 10 and near the surface of the substrate 1 (near the center of the light receiving potion 2), an effect of increasing the quantum efficiency is increased. In FIG. 1, the light scattering structure 6 provided in such a desirable position is illustrated. A reason for this is as follows. Note that, in FIG. 1, the light scattering structure 6 is illustrated in an elliptical shape, but there is no particular limitation on a shape of the light scattering structure 6.

Assume a case where the light scattering structure 6 is located near the flattening film 9 in the color filter 8. In this case, the incident light 31 scatters in a position apart from the light receiving potion 2, and therefore, there is a probability that an amount of light that enters the light receiving potion 2 is reduced. Moreover, the light scattering structure 6 is off the light-condensing point of the microlens, and therefore, an effect of scattering light can be achieved only for a portion of the incident light 31. Therefore, the light scattering structure 6 is preferably provided in a position near the light receiving potion 2 (the substrate 1). In particular, the light scattering structure 6 is preferably provided in a closest position to the light receiving potion 2 in the color filter 8.

Also in a case where the light scattering structure 6 is located in periphery of the light receiving potion 2 (the pixel 30) (near the light shielding layer 7), the light scattering structure 6 is off the light-condensing point of the microlens 10. As a result, the effect of scattering light is reduced. Therefore, the light scattering structure 6 is preferably located near the center of the light receiving potion 2.

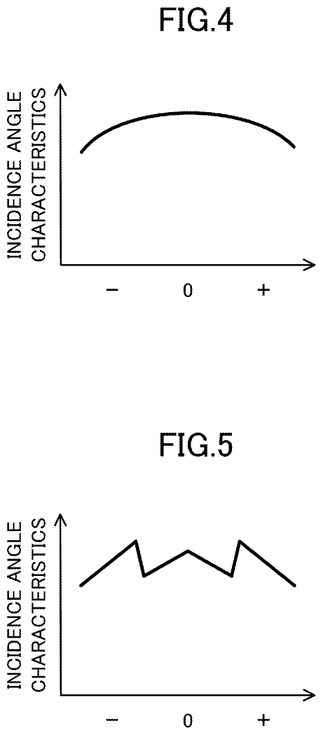

FIG. 4 illustrates incidence angle characteristics of the solid-state imaging device 50. That is, a case where light enters the solid-state imaging device 50 perpendicular thereto is indicated as 0, a case where the light entering the solid-state imaging device 50 is inclined to one side from a perpendicular direction is indicted plus (+), and a case where the light is inclined to an opposite side therefrom is indicated as negative (−). In a case where an incidence angle of light having the same intensity differs, when the incidence angle is 0, highest efficiency is achieved, so that a charge generated in the light receiving potion 2 is maximum. Although, as the incidence angle increases, the charge reduces, in the solid-state imaging device 50, change in magnitude of the charge with respect to the incidence angle is smooth. This is because scattering of light by the light scattering structure 6 does not have any specificity to the incidence angle.

In contrast to this, FIG. 5 illustrates incidence angle characteristics that can be generated in the solid-state imaging device of Japanese Unexamined Patent Publication No. 2016-001633. In this case, periodic inverted pyramid shapes are formed on the surface of the Si substrate, so that a specific refraction is generated with respect to the incidence angle. As a result, as illustrated in FIG. 5, the magnitude of the charge with respect to the incidence angle becomes irregular, and shading, moire, or the like is likely to occur in an image to be output, thus causing reduction in image quality. This can be prevented in the structure of the present disclosure.

### (Variation Related to Color Filter)

Next, a variation related to the color filter of the first embodiment will be described.

An example of the solid-state imaging device in which the color filter 8 is provided in the pixel 30 and that images a color image has been described above. However, in a solid-state imaging device that images a monochromatic image, similar effects can be achieved. In this case, instead of the color filter 8 in FIG. 1, a transparent film is formed. The light scattering structure 6 is provided in the transparent film, so that the quantum efficiency can be increased in a similar manner to that described above.

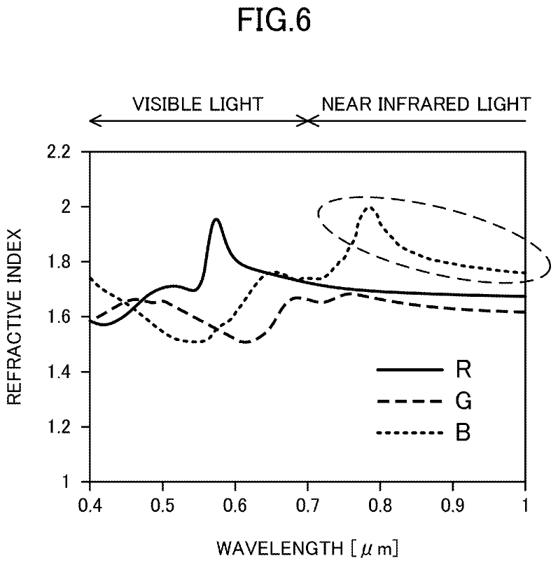

As the color filter 8, a blue filter containing a blue pigment may be employed. As illustrated in FIG. 6, the refractive index of the color filter depends on a wavelength of light. Curved lines R, G, and B indicate refractive indexes of color filters that contain a red pigment, a green pigment, and a blue pigment, respectively, for visible light and near infrared light. As illustrated in FIG. 6, for the near infrared light, the refractive index of the blue filter is high. Accordingly, the blue filter is employed for the color filter 8 around the light scattering structure 6, so that a difference between the refractive indexes is increased. As a result, an effect of increasing the quantum efficiency becomes significant. The above-described structure is useful for obtaining an image using only near infrared light.

### (Variation Related to Light Scattering Structure 6)

Next, a variation related to the light scattering structure 6 of the first embodiment will be described.

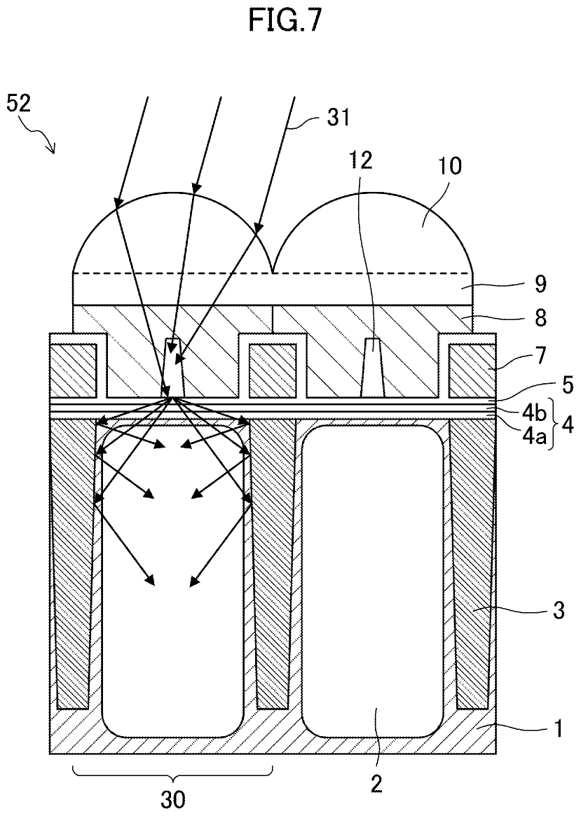

FIG. 7 illustrates a solid-state imaging device 52 of this variation. As compared to the solid-state imaging device 50 of FIG. 1, in the solid-state imaging device 52, a shape of the light scattering structure is specified. Other than that, the solid-state imaging device 52 has the same configuration to that of the solid-state imaging device 50, and therefore, a difference of the solid-state imaging device 52 from the solid-state imaging device 50 will be mainly described below.

Hereinafter, in the solid-state imaging device 52, a perpendicular direction to a surface of the substrate 1 will be referred to as a longitudinal direction and a dimension in this direction will be referred to as a height. Moreover, a horizontal parallel to the surface of the substrate 1 will be referred to as a lateral direction and a dimension in this direction will be referred to as a width. At this time, a light scattering structure 12 of the solid-state imaging device 52 has a longitudinally long shape, that is, a shape having a height that is longer than a width thereof.

Thus, even when light diagonally enters the pixel 30, the effect that the light scattering structure 12 scatters light can be easily maintained as in a manner below.

In FIG. 1, a case where incident light enters the pixel 30 perpendicular to the pixel 30 is illustrated. In this case, the described effect can be sufficiently achieved. However, in the solid-state imaging device 50 of FIG. 1, when the incident light 31 diagonally enters the pixel 30 as illustrated in FIG. 7, a deviation between the light-condensing point of the microlens 10 and the light scattering structure 6 occurs, and there is a probability that the effect of scattering light is reduced.

In contrast, in the solid-state imaging device 52 of FIG. 7, even when the incident light 31 diagonally enters the solid-state imaging device 52, the incident light 31 easily enters the light scattering structure 12 having a longitudinally long shape. Accordingly, reduction of the effect that the light scattering structure 12 scatters light can be suppressed. As a result, the quantum efficiency is more reliably increased even when the incident light 31 diagonally enters the solid-state imaging device 52. In an imaging area in which the pixels 30 are arrayed, an angle of the incident light 31 defers between a central portion and a peripheral portion, and therefore, it is useful for increasing the imager quality to suppress an influence of the difference therebetween. An influence of a difference of a lens of a camera using the solid-state imaging device 52 (F value or the like) can be also reduced.

The light scattering structure 12 is preferably configured to have a height that is 20% or more of a thickness of the color filter 8, and is more preferably configured to have a height that is 50% of the thickness. Thus, even when the incident light 31 diagonally enters the solid-state imaging device 52, light can easily enter the light scattering structure 12.

### (Shape of Light Scattering Structure in Plan View)

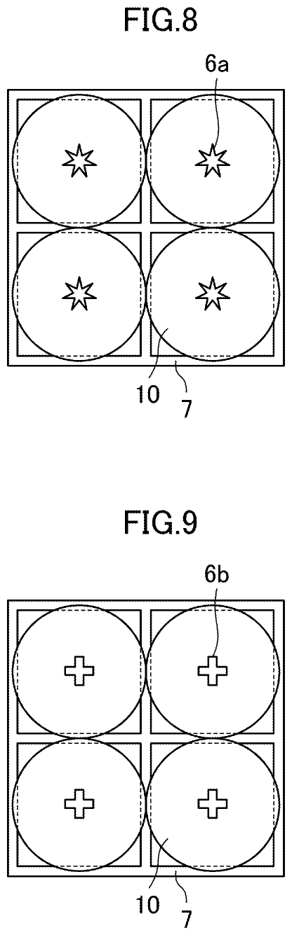

Next, the shape of the light scattering structure will be further described. FIG. 8 is a plan view of the solid-state imaging device 50 when viewed from the perpendicular direction to the surface of the substrate 1. In FIG. 8, for four pixels 30 in two rows and two columns, only the light shielding layer 7, the microlens 10, and a light scattering structure 6a are illustrated. Note that the light scattering structure 6a may have a longitudinally long shape as the light scattering structure 12 of FIG. 7, and may not have a longitudinally long shape. In FIG. 8, the light scattering structure 6a is located near the center of the pixel 30 (the light receiving potion 2). As described above, this is a desirable position.

In the plan view, the light scattering structure 6a preferably has a shape having a corner, specifically, a shape having a sharp-angled portion. As one example, the light scattering structure 6a may have a star shape that includes sharp-angled protrusions, as illustrated in FIG. 8. With such a shape, the incident light can be more effectively scattered. As a result, the quantum efficiency is increased.

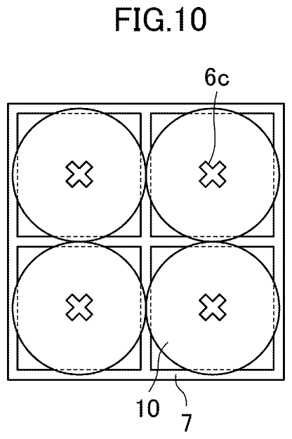

As a shape of the light scattering structure in a plan view, a shape with recesses and protrusions is preferable, and a cross shape may be employed. In FIG. 9 and FIG. 10, a light scattering structure 6b and a light scattering structure 6c each having a cross shape are illustrated. The light scattering structure 6b and the light scattering structure 6c have the same shape in a plan view, but orientations thereof are different. In such a structure, the effect of scatting the incident light 31 is achieved, and as a result, the effect of increasing the quantum efficiency is more reliably achieved.

### Second Embodiment

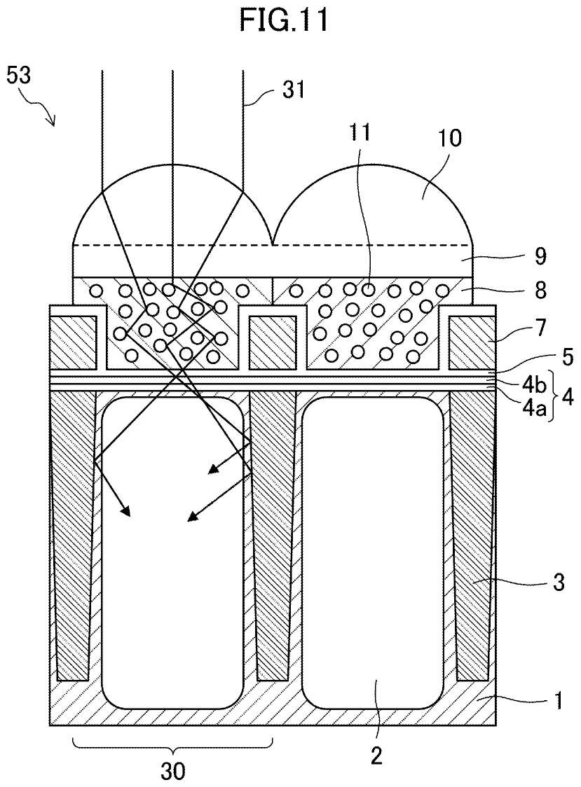

FIG. 11 is a schematic cross-sectional view illustrating an exemplary solid-state imaging device 53 according to a second embodiment. The solid-state imaging device 53 is similar to the solid-state imaging device 50 of FIG. 1 except for the light scattering structure, and a different of the solid-state imaging device 53 from the solid-state imaging device 50 will be mainly described below.

In the solid-state imaging device 50 of FIG. 1, one light scattering structure 6 is provided for each of the pixels 30. In contrast, in the solid-state imaging device 53 of this embodiment, a plurality of light scattering structures 11 are provided for each of the pixels 30. The light scattering structure 11 is formed, for example, hollow silica. That is, the color filter 8 contains hollow silica particles. When the incident light 31 that has transmitted through the microlens 10 enters the color filter 8, the incident light 31 is refracted and reflected by many silica particles (the light scattering structures 11) and enters the light receiving potion 2 at various angles. Accordingly, as compared to a case where the light scattering structures 11 are not provided as in FIG. 2, an optical path in the light receiving potion 2 becomes longer. As a result, the amount of absorption of light in the light receiving potion 2 is increased, and the quantum efficiency is increased.

It is similar to the first embodiment that the refractive indexes of the color filter 8 and the light scattering structures 11 are large (for example, 0.3 or more), that a transparent film is formed, instead of the color filter 8, as a monochromatic imaging device, and that, as the color filter 8, a blue filter is employed.

As another example, the light scattering structure 11 may be formed of an aggregate of a pigment. In this case, a difference in refractive index from the color filter 8 tends to be small. However, a shape of the aggregate of the pigment is distorted and irregular, and therefore, in this point, the effect of scattering light is large. The effect of scattering light can be suppressed by setting a dispersant and adjusting a size of the aggregate.

### (Effect of Light Scattering Structure)

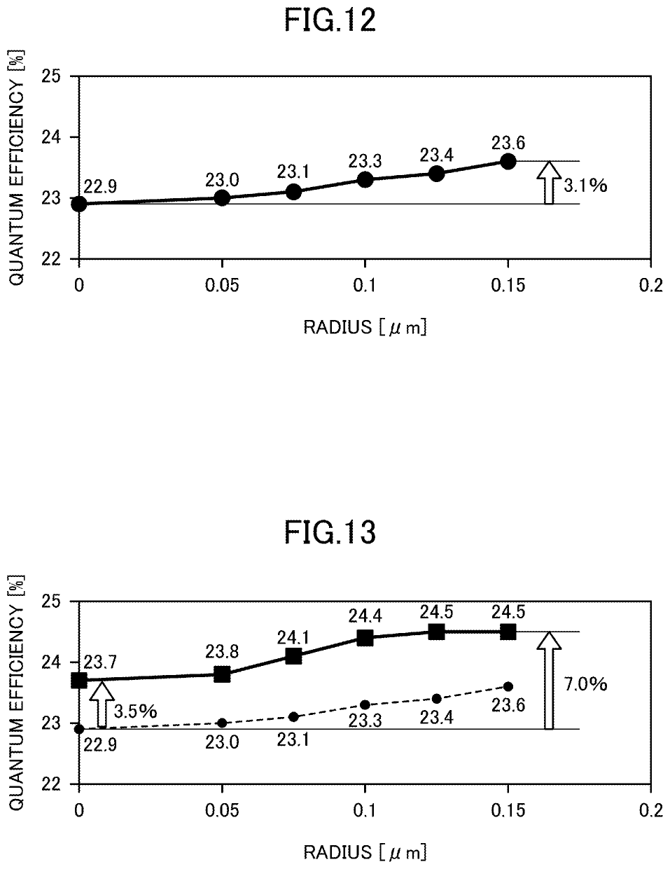

For the solid-state imaging device 53 of the second embodiment, an optical simulation of the quantum efficiency is performed. FIG. 12 illustrates a simulation result when hollow silica was used as the light scattering structures 11. Note that this is a case where, instead of the color filter 8, a transparent film was formed. An abscissa indicates a radius of the hollow silica and an ordinate indicates the quantum efficiency at a wavelength of 940 nm. A radius 0 corresponds to a case where the light scattering structures 11 were not provided.

As illustrated in FIG. 12, the quantum efficiency tends to increase as the radius of the hollow silica as the light scattering structures 11 increases. The quantum efficiency when the light scattering structures 11 were not provided was 22.9%, and in contrast, the quantum efficiency when the radius of the light scattering structures 11 was 0.15 μm was 23.6%. This is an increase by (23.6−22.9)/22.9×100≈3.1%.

Furthermore, FIG. 13 illustrates a simulation result when the light scattering structures 11 were formed in a blue filter. A broken line indicates the simulation result indicated in FIG. 12, and a solid line indicates the simulation result obtained when the blue filter was

As illustrated in FIG. 13, the quantum efficiency is further increased by using the blue filter. For a case where the radius of the light scattering structures 11 was 0.15μ, and the blue filter was used, the quantum efficiency was 24.5%. This is an increase by (24.5−22.9)/22.9×100≈7.0%, as compared to the case where the light scattering structures 11 were not provided.

As described above, a light scattering structure formed according to the present disclosure can increase the quantum efficiency without causing increase of the dark current and the white spot. Specific refraction as an incidence angle characteristic does not occur. As a result, a solid-state imaging device with high sensitivity and excellent image quality can be achieved.

### <Method for Manufacturing Solid-state Imaging Device>

Next, a method for manufacturing a solid-state imaging device according to the present disclosure (specifically, a method for forming a light scattering structure) will be described.

### (First Manufacturing Method)

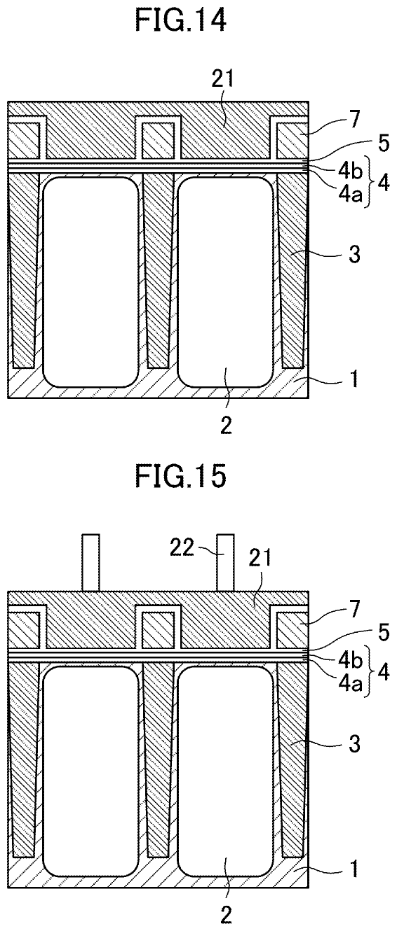

FIG. 14 to FIG. 17 are views illustrating a first method for manufacturing a solid-state imaging device according to the present disclosure.

In FIG. 14, the light receiving potion 2, the DTI region 3, the insulating film 4, the protective film 5, and the light shielding layer 7 are formed in the substrate 1. These components can be formed, for example, by the following method. The light receiving potion 2 is formed by introducing an impurity to the substrate 1 by ion implantation or the like. The DTI region 3 is formed by forming a trench in the substrate 1 by etching or the like and filling an insulating film (a silicon oxide film or the like) in the trench. The insulating film 4 and the protective film 5 are formed as a silicon oxide film, a silicon nitride film, or the like by chemical vapor deposition (CVD) or the like. The light shielding layer 7 is formed by forming, after forming a tungsten film to cover the substrate 1, a resist pattern, and then, removing a portion other than a necessary portion. Note that some other method may be used to form the above-described components.

When the light shielding layer 7 (and a portion of the protective film 5 thereon) are formed so as to surround the pixel 30, a recessed portion is formed above the light receiving potion 2 for each of the pixels 30.

Thereafter, a low refractive index material film 21 is formed so as to fill the recessed portion. FIG. 14 illustrates a state where the above-described steps are completed.

Next, as illustrated in FIG. 15, a resist pattern 22 is formed on the low refractive index material film 21. The resist pattern 22 is formed, for example, by, after forming a resist on the entire low refractive index material film 21, performing patterning using a lithograph technique.

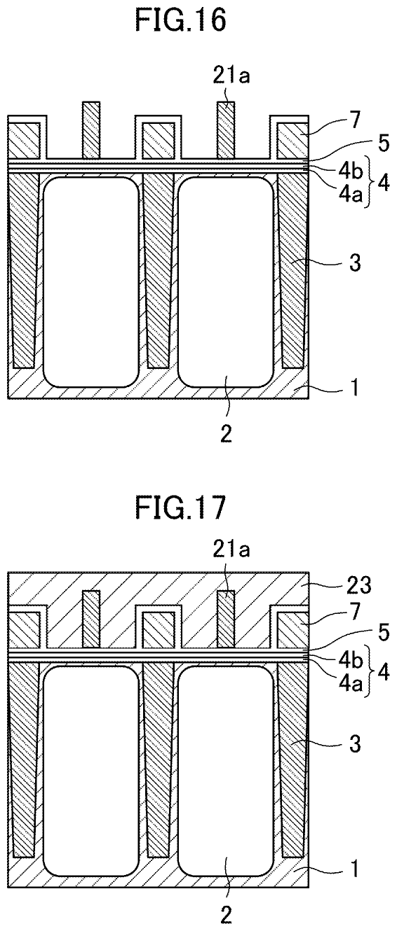

Next, as illustrated in FIG. 16, etching is performed using the resist pattern 22 as a mask to form a low refractive index material pattern 21a of the low refractive index material film 21.

Next, as illustrated in FIG. 17, thereafter, a high refractive index material film 23 having a higher refractive index than that of the low refractive index material film 21 and the low refractive index material pattern 21a is buried therein. Thus, a structure in which the low refractive index material pattern 21a serves as a light scattering structure and the color filter 8 as the high refractive index material film 23 is formed therearound is obtained. Thereafter, the flattening film 9 and the microlens 10 are formed, thereby manufacturing the solid-state imaging device illustrated in FIG. 1 or FIG. 7.

Note that the low refractive index material film 21 is a transparent film containing, for example, polysiloxane.

According to this method, position and shape of the light scattering structure 6 or the light scattering structures 11 in a plan view can be determined by setting position and shape of the resist pattern 22. Thus, the light scattering structure can be set in the center of the light receiving potion 2, and the shapes of the light scattering structure illustrated as examples in FIG. 8 to FIG. 10 can be set. Moreover, the longitudinally long shape of the light scattering structures 11 can be achieve by setting a thickness of the low refractive index material film 21 or the like.

### (Second Manufacturing Method)

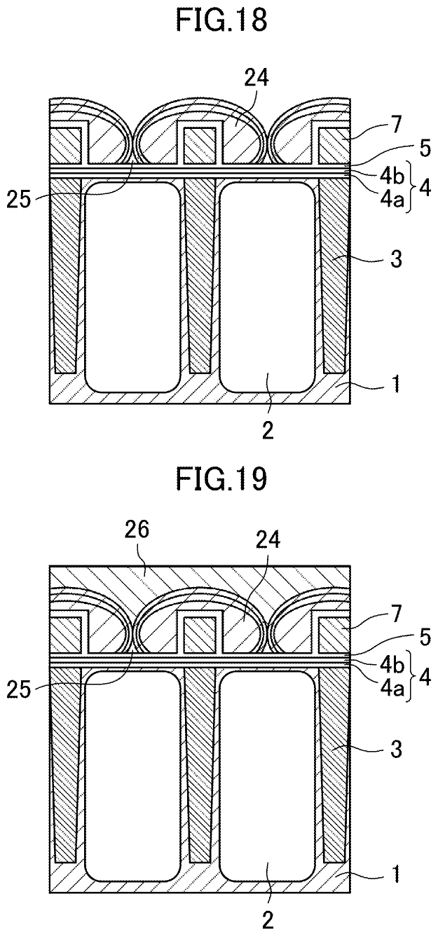

FIG. 18 to FIG. 19 are views illustrating a second method for manufacturing a solid-state imaging device according to the present disclosure.

In FIG. 18, the light receiving potion 2, the DTI region 3, the insulating film 4, the protective film 5, and the light shielding layer 7 are formed in the substrate 1. These components can be formed in a similar manner to the first manufacturing method.

In a state where the recessed portion is formed above the light receiving potion 2 by the light shielding layer 7, a material film 24 is formed by CVD. At this time, a film grows isotropically on the upper and side surfaces of the light shielding layer 7. As a result, as illustrated in FIG. 18, a void (cavity) 25 can be left around the center of the light receiving potion 2 in a plan view. That is, film deposition is performed such that the recessed portion is not completely filled.

Thereafter, as illustrated in FIG. 19, a material film 26 is further formed on the material film 24 such that an entire thickness becomes sufficient.

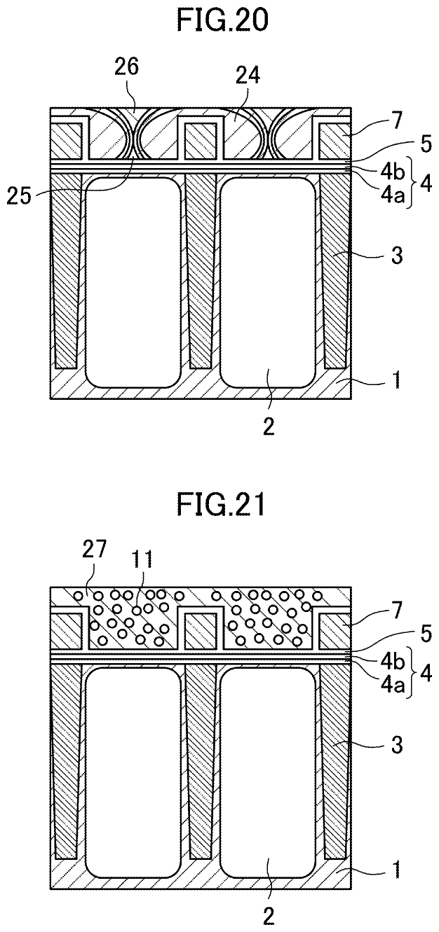

Subsequently, as illustrated in FIG. 20, the entire portion is etched back to a predetermined thickness to flatten respective upper surfaces of the material film 24 and the material film 26. Thus, the void 25 is formed in the material films 24 and 26. Thereafter, the flattening film 9 and the microlens 10 are formed, thereby manufacturing a solid-state imaging device according to the present disclosure.

According to this manufacturing method, a solid-state imaging device in which the material films 24 and 26 function as the color filter 8 and the void 25 functions as the light scattering structure can be achieved.

### (Third Manufacturing Method)

FIG. 21 to FIG. 23 are views illustrating a third method for manufacturing a solid-state imaging device according to the present disclosure. The third manufacturing method is a method for manufacturing the exemplary solid-state imaging device 53 of the second embodiment.

In FIG. 21, the light receiving potion 2, the DTI region 3, the insulating film 4, the protective film 5, and the light shielding layer 7 are formed in the substrate 1. These components can be formed in a similar manner to the first manufacturing method.

A color resist 27 containing hollow silica or an aggregate of a pigment as the light scattering structures 11 is applied such that the recessed portion formed above the light receiving potion 2 is filled with the light shielding layer 7. Exposure and development are performed on the color resist 27, thereby forming a pattern of the color resist 27 including the light scattering structures 11 in a desired position.

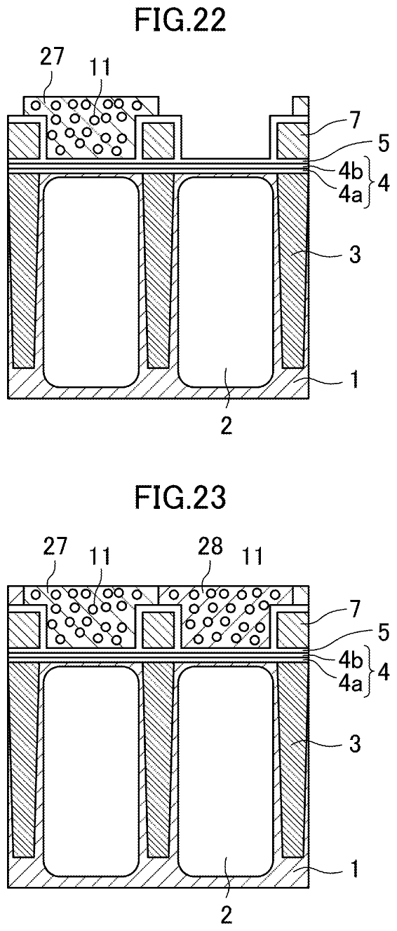

In FIG. 22, a pattern of the color resist 27 is formed in one of the pixels 30.

Thereafter, similar application, exposure, and development are performed, thereby forming a pattern of a color resist 28 corresponding to another color for another one of the pixels 30. The color resist 28 also includes the light scattering structures 11. This state is illustrated in FIG. 23.

Although only two of the pixels 30 are illustrated in the drawings, for example, for a solid-state imaging device having color filters of three colors R, G, and B, similar processing is further performed again. Thereafter, the flattening film 9 and the microlens 10 are formed, thereby manufacturing the solid-state imaging device 53 illustrated in FIG. 11.

This manufacturing method is similar to a typical known manufacturing method, except that the light scattering structures 11 (hollow silica, an aggregate of a segment, or the like) are mixed in a color resist. That is, to provide the light scattering structures 11, there is no need to add a special process.

Note that, in a monochromatic imaging device, instead of the color resist, a transparent film including the light scattering structures 11 may be formed.

According to the technology disclosed herein, the quantum efficiency can be increased while reduction in image quality is suppressed, and therefore, the technology disclosed herein is useful for a solid-state imaging device.

What is claimed is:

1. A solid-state imaging device comprising:
a plurality of pixels arrayed in a two-dimensional matrix on a substrate,
wherein
each of the pixels includes a light receiving potion that performs photoelectric conversion, a microlens that condenses light to the light receiving potion, and at least one light scattering structure provided between the light receiving potion and the microlens.

2. The solid-state imaging device according to claim 1, wherein
a refractive index of the light scattering structure is lower than a refractive index of a portion around the light scattering structure.

3. The solid-state imaging device according to claim 1, wherein
a refractive index of a material that forms the light scattering structure is lower than a refractive index of a material of a portion around the light scattering structure by 0.3 or more.

4. The solid-state imaging device according to claim 1, wherein
the light scattering structure is formed of a void.

5. The solid-state imaging device according to claim 1, wherein
the light scattering structure is formed of hollow silica.

6. The solid-state imaging device according to claim 1, wherein
a blue filter is provided between the light receiving potion and the microlens, and
the light scattering structure is provided in the blue filter.

7. The solid-state imaging device according to claim 1, wherein
the light scattering structure is formed of an aggregate of a pigment.

8. The solid-state imaging device according to claim 1, wherein
at least one light scattering structure is provided for each of the pixels.

9. The solid-state imaging device according to claim 1, wherein
the light scattering structure is provided near the light receiving potion.

10. The solid-state imaging device according to claim 1, wherein
the light scattering structure is provided near a center of the light receiving potion when viewed from a perpendicular direction to a surface of the substrate.

11. The solid-state imaging device according to claim 1, wherein
the light scattering structure has a shape that is long in a perpendicular direction to a surface of the substrate.

12. The solid-state imaging device according to claim 1, wherein
the light scattering structure has a shape having a plurality of sharp-angled portions when viewed from a perpendicular direction to a surface of the substrate.

13. The solid-state imaging device according to claim 1, wherein
the light scattering structure has a cross shape when viewed from a perpendicular direction to a surface of the substrate.

14. A method for manufacturing a solid-state imaging device, the method comprising:
forming a plurality of light receiving potions arrayed in a two-dimensional matrix on a substrate; and
forming a light scattering structure on each of the light receiving potions.

15. The method for manufacturing a solid-state imaging device according to claim 14, wherein
the forming a light scattering structure includes
forming a first material film that covers the light receiving potions,
patterning the first material film such that the first material film is left in a predetermined shape on each of the light receiving potions, and
forming a second material film having a higher refractive index than a refractive index of the first material film such that the second material film covers a portion around the patterned first material film.

16. The method for manufacturing a solid-state imaging device according to claim 14, wherein
the forming a light scattering structure includes
forming a recessed portion above each of the light receiving potions by forming a light shielding layer that surrounds each of the light receiving potions on the substrate, and
filling the recessed portion such that a void is left over each of the light receiving potions by forming a material film on side and upper surfaces of the light shielding layer by isotropic chemical vapor deposition.

17. The method for manufacturing a solid-state imaging device according to claim 14, wherein
the forming a light scattering structure incudes
forming a resist film containing hollow silica or an aggregate of a pigment, and
patterning the resist film.
